(19) United States
(12) Patent Application Publication
(10) Pub. No.: US 2012/0097211 A1
(43) Pub. Date: Apr. 26, 2012

(54) Electric power generators and systems comprising same

(76) Inventors: Pinchas Gurfil, Haifa (IL); Joseph Cory, Haifa (IL)

(21) Appl. No.: 12/007,867

(22) Filed: Jan. 16, 2008

Related U.S. Application Data
(60) Provisional application No. 60/880,366, filed on Jan. 16, 2007.

(51) Int. Cl. H01L 31/052; B64B 1/50

(52) U.S. Cl. 136/246; 244/33

(57) ABSTRACT

An electric power generator comprising: at least one lighter than air balloon (LAB) with at least one photovoltaic array (PVA) embedded in a surface thereof; and a cable connecting the LAB to the ground and adapted to convey a buoyant gas to an inner volume of the LAB and also to convey an electric current generated by said PVA to a ground installation.

This application claims benefit under §119(e) of prior U.S. provisional patent application No. 60/880,366 filed Jan. 16, 2007, the contents of which are hereby incorporated by reference in their entirety.

### FIELD OF THE INVENTION

This invention relates to solar energy collectors installed on lighter than air balloons.

### BACKGROUND OF THE INVENTION

The persistently increasing energy cost and the forthcoming energy crisis necessitates the development of alternative energy resources. Ultimately, the goal of alternative energy is to provide clean, inexpensive, reliable and sustainable energy to every consumer on the globe. Solar energy is one of the most promising clean energy sources. Numerous applications and technologies utilizing the photovoltaic effect, ranging from cellular phones to geostationary satellites, have been developed in recent decades. We suggest using solar power by designing lighter-than-air platforms (balloons and blimps) carrying an embedded array of solar cells.

The lighter-than-air craft technology has been proven useful for a myriad of commercial, military and civil applications, including meteorological balloons, intelligence blimps, and stratospheric observatories [1]. Connecting an exterior solar array to airborne platforms such as balloons, kites and general aviation aircraft [2], or use of a ground system comprising a balloon with an embedded solar array [3] has been proposed. Others proposed using a lighter-than-air airship to collect solar power and to beam it back to Earth using microwave radiation [4].

Solar radiation reaches the Earth's upper atmosphere at a rate of 1,366 W/m² [5]. While traveling through the atmosphere, 6% of the incoming solar radiation (insolation) is reflected and 16% is absorbed, resulting in a peak irradiance at the equator of 1,020 W/m² [6]. Average atmospheric conditions (clouds, dust, pollution) reduce insolation by 20% through reflection and 3% through absorption. In addition to affecting the quantity of insolation reaching the surface, atmospheric conditions also affect the quality of insolation reaching the surface by diffusing incoming light and altering its spectrum.

For example, in North America the average insolation lies between 125 and 375 W/m² (3 to 9 kWh/m²/day) [7]. This is the available power, and not the delivered power. Photovoltaic panels currently convert about 15-25% of incident sunlight into electricity; therefore, a solar panel in the contiguous United States on average delivers 19 to 100 W/m² or 0.45-2.7 kWh/m²/day [8]. In addition, Solar cells produce DC which must be converted to AC when used in currently existing distribution grids. This incurs an energy penalty of 4-12%.

The advantages of solar energy are abundant. The 122 PW of sunlight reaching the earth's surface is plentiful compared to the 13 TW average power consumed by humans. Additionally, solar electric generation has the highest power flux (20-60 W/m²) among renewable energies. Moreover, solar power is pollution-free during use. Solar electric generation is economically competitive where grid connection or fuel transport is difficult, costly or impossible. Examples include satellites, island communities, remote locations and ocean vessels.

When grid connected, solar electric generation can displace the highest cost electricity during times of peak demand (in most climatic regions), can reduce grid loading, and can eliminate the need for local battery power for use in times of darkness and high local demand.

The main disadvantage of solar electricity is limited power density, requiring relatively large collecting sites, occupying considerable land. In this work, we propose to mitigate this deficiency by designing a lighter-than-air system for collecting solar electricity. This concept may be used to backup existing power plants or as a primary energy sources in countries where land resources are scarce.

### SUMMARY OF THE INVENTION

An aspect of some embodiments of the invention relates to designs for generating electric power using lighter than air balloons (LAB) carrying embedded solar cells. In some exemplary embodiments of the invention, the balloons are strapped to the ground. Optionally, strapping to the ground is with dual-use insolated cables, carrying helium to the balloon and transporting electric charge towards the ground.

In some exemplary embodiments of the invention, LAB are filled with helium. Optionally, helium offers one or more improved performance characteristics with respect to hot air. Improved performance characteristics include, but are not limited to, a low boiling point, a low density, a low solubility, a high thermal conductivity, and inertness. Alternatively or additionally, pressurized helium is commercially available in large quantities. Because helium has a low index of refraction, use of helium can reduce distorting effects of temperature variations in a space between. Alternatively or additionally, positive buoyancy of un-heated helium offers an environmental advantage over hot-air systems which can contribute to ozone depleting. Optionally, use of helium reduces a global warming effect.

An aspect of some embodiments of the invention relates to aerodynamically-shaped balloons capable of mitigating wind effects such as lift and/or drag.

An aspect of some embodiments of the invention relates increasing a balloon surface area per volume ratio. In some exemplary embodiments of the invention, an increase in this ratio contributes to an increase in generated power.

In some exemplary embodiments of the invention, LAB carry low-cost, off-the-shelf components such as solar arrays and wires. Optionally, LAB are anchored using a dual-use isolated cable, capable of conducting electricity and providing helium to the balloon. Optionally, collected power is delivered to the ground using the balloon cable. Optionally, delivered power is transformed from DC to AC and/or regulated to provide a stable source of power according to defined voltage and/or current parameters. In some exemplary embodiments of the invention, generated heat is radiated from a surface of the LAB. Optionally, no additional radiators are provided. In some exemplary embodiments of the invention, the specific heat capacity of helium contributes to implementation of passive cooling.

The term “lighter than air balloon” or “LAB” as used herein refers to any inflatable body with positive buoyancy in air. While exemplary embodiments of LAB with defined geometric configurations are described, the invention is not limited by any specific geometric configuration.

In some exemplary embodiments of the invention, there is provided an electric power generator, the generator including:
at least one lighter than air balloon (LAB) with at least one photovoltaic array (PVA) embedded in a surface thereof; and
a cable connecting the LAB to the ground and adapted to convey a buoyant gas to an inner volume of the LAB and also to convey an electric current generated by the PVA to a ground installation.

Optionally, the PVA are embedded in an outer surface of the LAB.

Optionally, a portion of the LAB is transparent with respect to desired wavelengths of light.

Optionally, the PVA are embedded in an inner surface of the LAB.

Optionally, at least a portion of an inner surface of the LAB is reflective with respect to the desired wavelengths of light.

Optionally, the LAB includes:
a lower paraboloid portion; and
an upper paraboloid portion inverted with respect to the lower paraboloid portion.

In some exemplary embodiments of the invention, there is provided an electric power generator, the generator including:
at least one lighter than air balloon (LAB) including an upper portion constructed of material transparent with respect to desired wavelengths of incident light and a lower portion adapted to receive the desired wavelengths of incident light on an inner surface thereof; and
at least one photovoltaic array (PVA) on an inner surface of the LAB.

Optionally, the at least one PVA resides on the inner surface of the lower portion.

Optionally, the at least one PVA resides on an inner surface of the upper portion and the lower portion receives the desired wavelengths of incident light on a reflective inner surface which directs the light to the PVA.

Optionally, at least one of the upper portion and the lower portion is configured as a paraboloid.

Optionally, the upper portion and the lower portion are each configured as paraboloids inverted with respect to one another.

In some exemplary embodiments of the invention, there is provided an anchored lighter than air balloon (LAB), the balloon including:
an upper portion and a lower portion, each of the portions configured as paraboloids inverted with respect to one another;
a circumferential closure joining the upper and lower portions; and
an anchor connecting at least three points on the circumferential closure to an anchor point.

Optionally, the anchor is adapted to convey a buoyant gas to the balloon.

Optionally, the LAB includes at least one PVA embedded in a surface of the balloon.

In some exemplary embodiments of the invention, there is provided a generator as described above including an interface to a ground based power grid.

In some exemplary embodiments of the invention, there is provided a power supply system including:
a plurality of generators as described above deployed in a three dimensional array and connected to one another; and
an interface to a ground based power grid.

In some exemplary embodiments of the invention, there is provided an LAB according as described above including an interface between the PVA and a ground based power grid.

In some exemplary embodiments of the invention, there is provided power supply system including:
a plurality of LAB as described above deployed in a three dimensional array and connected to one another, and
an interface between the PVA of the plurality of LAB and a ground based power grid.

Unless otherwise defined, all technical and scientific terms used herein have the same meaning as commonly understood by one of ordinary skill in the art to which this invention belongs. Although suitable methods and materials are described below, methods and materials similar or equivalent to those described herein can be used in the practice of the present invention. In case of conflict, the patent specification, including definitions, will control. All materials, methods, and examples are illustrative only and are not intended to be limiting.

As used herein, the terms “comprising” and “including” or grammatical variants thereof are to be taken as specifying inclusion of the stated features, integers, actions or components without precluding the addition of one or more additional features, integers, actions, components or groups thereof. This term is broader than, and includes the terms “consisting of” and “consisting essentially of” as defined by the Manual of Patent Examination Procedure of the United States Patent and Trademark Office.

The phrase “consisting essentially of” or grammatical variants thereof when used herein are to be taken as specifying the stated features, integers, steps or components but do not preclude the addition of one or more additional features, integers, steps, components or groups thereof but only if the additional features, integers, steps, components or groups thereof do not materially alter the basic and novel characteristics of the claimed composition, device or method.

The term “method” refers to manners, means, techniques and procedures for accomplishing a given task including, but not limited to, those manners, means, techniques and procedures either known to, or readily developed from known manners, means, techniques and procedures by practitioners of architecture and/or computer science.

### BRIEF DESCRIPTION OF THE DRAWINGS

In order to understand the invention and to see how it may be carried out in practice, embodiments will now be described, by way of non-limiting example only, with reference to the accompanying figures. In the figures, identical and similar structures, elements or parts thereof that appear in more than one figure are generally labeled with the same or similar references in the figures in which they appear. Dimensions of components and features shown in the figures are chosen primarily for convenience and clarity of presentation and are not necessarily to scale. The attached figures are:

FIG. 1 is a schematic representation of a lighter than air balloon (LAB) according to some exemplary embodiments of the invention;

FIG. 2 is a schematic representation of an LAB according to additional exemplary embodiments of the invention;

FIG. 3 is a schematic representation of an LAB according to further additional exemplary embodiments of the invention;

FIGS. 4A, 4B and 4C are views of LAB according to FIG. 2 or FIG. 3 from different angles;

FIG. 5 is a diagram illustrating an exemplary arrangement of individual photovoltaic arrays (PVA) according to some exemplary embodiments of the invention;

FIG. 6 is a side view of a LAB according to exemplary embodiments of the invention illustration connection to exemplary ground based components;

FIG. 7 is a cross sectional view of a connecting cable according to some exemplary embodiments of the invention.

FIG. 8 is a horizontal cross section of an exemplary LAB according to some embodiments of the invention depicting an exemplary arrangement of PVA;

FIG. 9 is a transverse cross section of an exemplary LAB according to some embodiments of the invention depicting exemplary forces

FIG. 10 depicts deployment of exemplary LAB according to some embodiments of the invention in a rural area;

FIG. 11 depicts deployment of an exemplary LAB according to some embodiments of the invention in a desert area;

FIG. 12 depicts deployment of exemplary LAB according to some embodiments of the invention above a forest;

FIG. 13 depicts deployment of an exemplary LAB according to some embodiments of the invention in marine context;

FIG. 14 depicts deployment of an exemplary spatial array of LAB according to some embodiments of the invention; and

FIG. 15 depicts deployment of another exemplary spatial array of LAB according to additional embodiments of the invention.

### DETAILED DESCRIPTION OF EMBODIMENTS

Embodiments of the invention relate to anchored lighter than air balloons (LAB) with solar photovoltaic arrays (PVA) mounted on one or more surfaces thereof. Optionally, the LAB employ helium for positive buoyancy. Specifically, some embodiments of the invention can be used to supply electric power to a ground based power grid.

The principles and operation of LAB according to exemplary embodiments of the invention may be better understood with reference to the drawings and accompanying descriptions.

Before explaining at least one embodiment of the invention in detail, it is to be understood that the invention is not limited in its application to the details set forth in the following description or exemplified by the Examples. The invention is capable of other embodiments or of being practiced or carried out in various ways. Also, it is to be understood that the phraseology and terminology employed herein is for the purpose of description and should not be regarded as limiting.

### Exemplary Spherical Collector

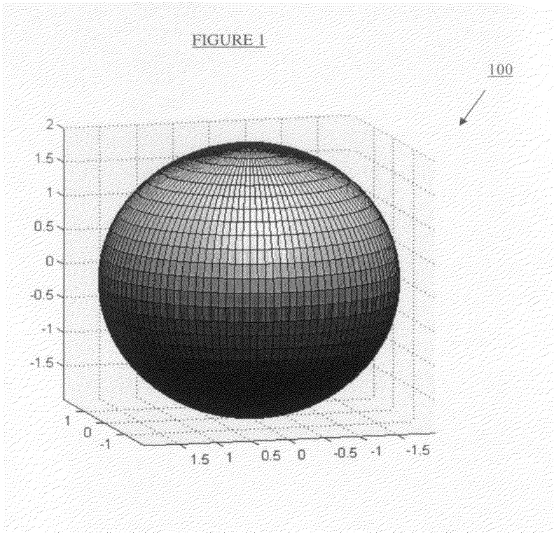

Consider a spherical helium-filled balloon (generally depicted as 100) whose outer surface is at least partially covered by a plurality of PVA, as shown in FIG. 1. For a given sphere radius, R, the Cartesian equation is

x²+y²+z²=R (1)

The surface area of the sphere is given by

S=4πR² (2)

and the volume is

V=4πR³/3 (3)

If the balloon is filled with helium, the maximal mass that can be lifted depends on the balloon volume, the air density and the helium density:

m=[ρₐᵢᵣ(H,Tₐ)−ρ_{He}(Tᵢ,Tₐ)]V_{balloon} (4)

where m is the total balloon mass, ρₐᵢᵣ(H,Tₐ) is the altitude- and ambient temperature-dependent density of air and ρ_{He}(Tᵢ,Tₐ) is the balloon-temperature- and ambient temperature-dependant density of helium. The maximal allowable mass can be therefore obtained by substituting the air density at sea-level, ρₐᵢᵣ=1.225 kg/m³, and the standard density of helium at room temperature, ρ_{He}=0.1786 kg/m³. For example, if R=2.12 m (this particular value is chosen so as to facilitate the comparison with the alternative design discussed in §4), then V≈40 m³, and m=41.84 kg. The helium mass is 7.14 kg, so the total “dry” mass is 34.7 kg.

This mass includes the light-weight structure, wiring, solar panels and radiators. If the total mass is less than 41.84 kg, then the balloon will rise above sea level. The maximum altitude can be obtained by first calculating the density,

$${ρ}_{air} ( H , {T}_{a} ) = \frac{m}{{V}_{balloon}} + {ρ}_{He} ( {T}_{i} , {T}_{a} ) \qquad ( 5 )$$

and then using standard atmosphere tables 0 to convert the resulting air density into altitude. For example, if the total mass (including helium) is 35 kg, then ρₐᵢᵣ=1.05 kg/m³, corresponding to an altitude of above 1500 m above sea level.

The total power generated by this balloon, assuming that only the upper hemisphere is exposed to sunlight, can be obtained by means of the relationship

P=Pₛᵤₙ·S·η_{PVA}/2 (6)

where Pₛᵤₙ is the total energy flux from the sun, and η_{PVA} is the Silicone or Gallium-Arsenide semi-conductors photon-to-voltage conversion efficiency (usually in the range 0.15-0.25).

Substituting R=2.12 m into Eq. (2) yields S=56.54 m². The average incoming solar radiation is assumed to be Pₛᵤₙ=500 W/m². Let η_{PVA}=0.15 (this value is typical for a standard design of solar arrays). Substituting these values into Eq. (6) yields P=2.12 kW. Hence, the balloon in our example is capable of supplying about 2 kw of electrical power. The power per unit volume is then

$$\frac{P}{V} = 53 W / {m}^{3} \qquad ( 7 )$$

### Exemplary Paraboloidic Reflector—Collectors

Spherical LAB 100 as described above is simple to implement as it relies on existing LAB designs. However, a spherical, or nearly spherical, shape is inherently susceptible to aerodynamic forces (e.g. lift and/or drag). Alternatively or additionally, a ratio of surface area to volume in a sphere is relatively low. In some exemplary embodiments of the invention, increasing the ratio of surface area to volume contributes to an increase in power return per unit volume.

Two alternative exemplary designs which increase the ratio of surface area to volume are described here. In each of these exemplary designs, the LAB includes two paraboloids inverted one with respect to the other. In both exemplary designs, electric power generated by solar collectors is collected and conducted to a ground system. Optionally, the ground system includes a DC/AC inverter and/or a power regulation and/or a control unit.

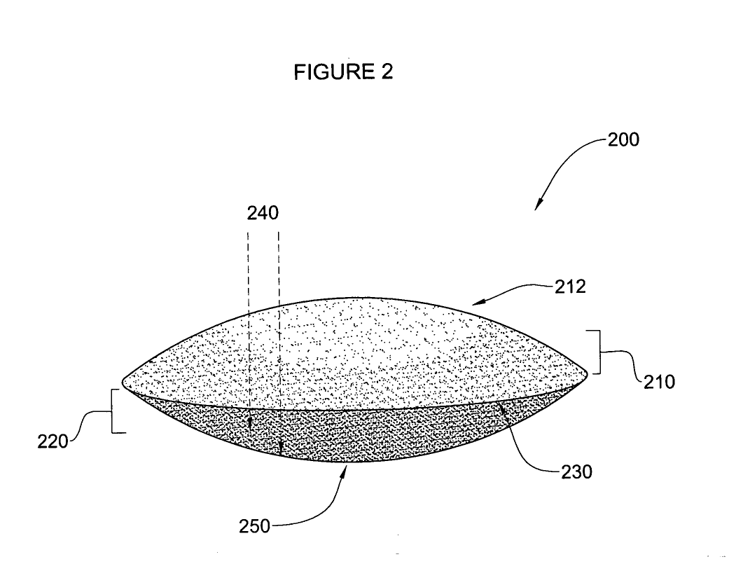

FIG. 2 depicts a first exemplary design generally indicated as 200 in which an upper part 212 of paraboloid 210 is transparent and a bottom paraboloid 220 contains PVA collectors 250 (optionally paraboloidic) on an inner surface thereof. Optionally, collectors 250 are provided embedded in an inner surface of lower paraboloid 210. In some exemplary embodiments of the invention, this design contributes to an increase in insolation conversion efficiency of incident light 240. In the depicted embodiment paraboloids 210 and 220 are connected to one another by a circumferential seal 230 so that they form LAB 200.

FIG. 2 depicts a second exemplary design generally indicated as 300. This second design is similar to the first design except that collectors 250 are replaced by reflectors 350 on an inner surface of paraboloid 220. Optionally, reflector 350 is provided embedded in the inner surface. According to this second exemplary design, incident light 240 is reflected and focused reflectors 350 back towards upper paraboloid 210 which contains an appropriately positioned photovoltaic array (PVA) 360. For example, PVA 360 can be positioned at the focal length of reflector 350 of bottom paraboloid 220.

One of ordinary skill in the art will be able to focus solar radiation using reflectors (e.g. 350) by employing principles known for concentrating streaming light in optical telescopes, parabolic antennae and previously available parabolic solar energy collectors. Optionally, a parabolic or paraboloidic design of the PVA can increase the insolation-to-electricity conversion efficiency.

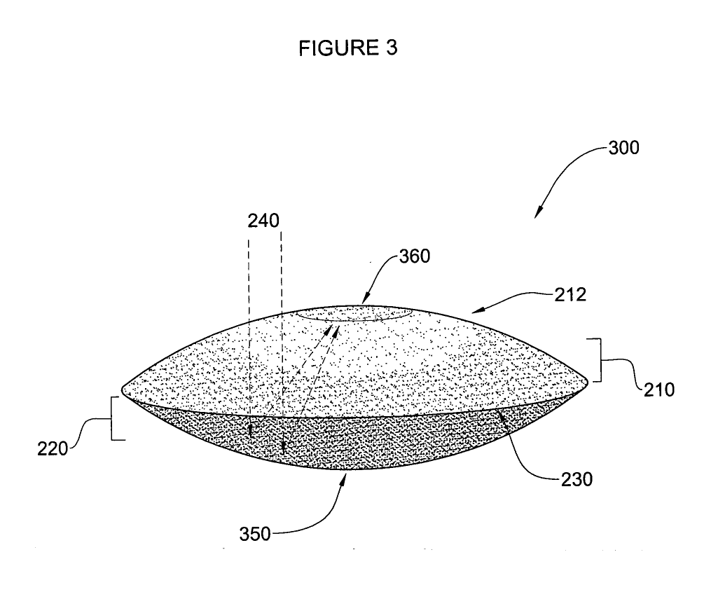

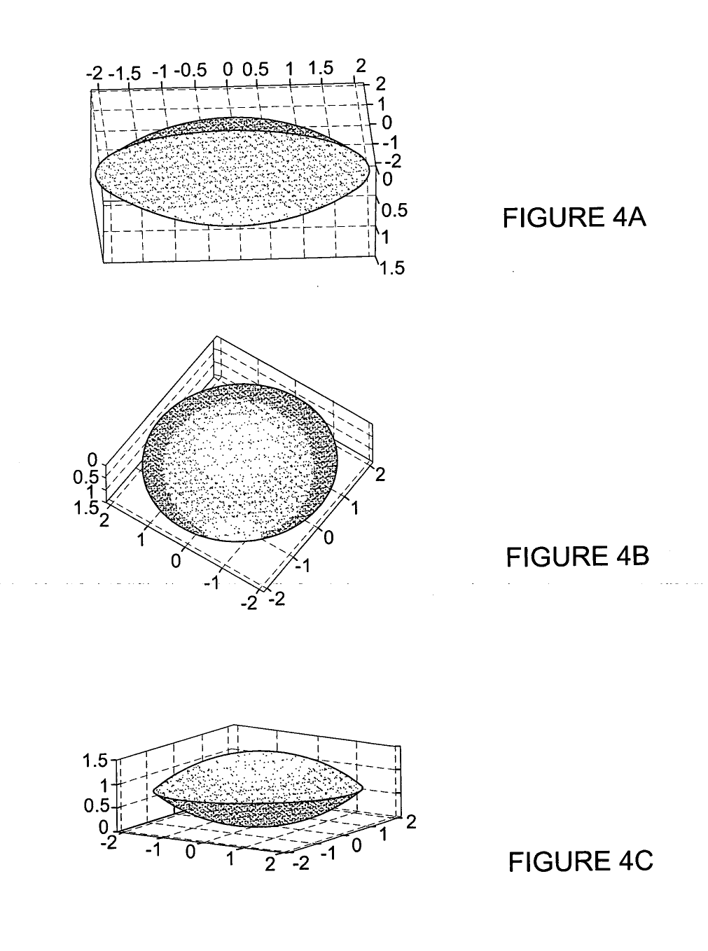

FIG. 4 depicts additional geometric views of the embodiments of FIG. 3. FIG. 4A is a perspective view from slightly below circumferential seal 230. FIG. 4B is a perspective view from slightly above circumferential seal 230. FIG. 4C is a top view. These different views illustrate bottom and top circular paraboloids (220 and 210 respectively), whose geometric properties are determined so that the focal length of reflector 350 coincides with a vertex of upper paraboloid 210.

To quantify this concept, recall that a paraboloid is the surface of revolution of the parabola. The resulting quadratic surface satisfies the Cartesian equation

$$z = \frac{1}{4 a} ( {x}^{2} + {y}^{2} ) \qquad ( 8 )$$

In this case, the focus is located at z=a. Since the focus is the only parameter defining the parabola (the distance from the focus to vertex is equal to the distance from the focus to the directrix, by definition), this constraint defines the maximal height of the reflector, the collecting surface area, the total volume, and the maximal airborne mass. These, in turn, together with given loss factors, determine the maximal power which can be generated using the balloon.

In general, a circular paraboloid that has radius α at height h is given by the parametric equations [9]

x(u,v)=α\sqrt{u/h} cos v (9)

y(u,v)=α\sqrt{u/h} sin v (10)

z(u,v)=u (11)

where u≧0, vε[0, 2π].

The surface area of the paraboloid satisfies [10]

$$S = \frac{πα}{6 {h}^{2}} [ {( {α}^{2} + 4 {h}^{2} )}^{3 / 2} - {α}^{3} ] \qquad ( 12 )$$

and the volume is given by [10]

$$V = \frac{1}{2} {πα}^{2} h \qquad ( 13 )$$

Thus, the total volume of the balloon and the total collecting area of the bottom collector/reflector satisfy, respectively,

V_{balloon}=2V,S_{collector/reflector}=S (14)

In order for the focus of the reflector, a, to lie on the uppermost point of the collector, we must select a maximum paraboloid height of h=a/2. This, in turn, defines the reflector maximal radius:

$$α = \sqrt{2 a} , for 0 \leq u \leq h = \frac{a}{2} \qquad ( 15 )$$

To illustrate the idea, consider the balloon shown in FIG. 4. The reflector (bottom paraboloid) has a focal length of a=1.5 m. This yields h=0.75 m and α=2.45 m. Substituting into (14) yields V_{balloon}=10.6 m³. To find the maximal allowable mass for this balloon, we shall use Eq. (4).

The maximal allowable mass can be obtained by substituting the air density at sea-level, ρₐᵢᵣ=1.225 kg/m³, and the standard density of helium at room temperature, ρ_{He}=0.1786 kg/m³, into Eq. (4), yielding mₘₐₓ=11.1 kg. The total mass of helium is 0.1786·V_{balloon}=1.89 kg, so the maximum dry mass is 9.2 kg. This mass includes the light-weight structure, wiring, and solar panels. If the total mass is less than 9.2 kg, then the balloon will rise above sea level. The maximum altitude can be obtained by Eq. (5). For example, if the total mass (including helium) is 10 kg, then ρₐᵢᵣ=1.12 kg/m³, corresponding to an altitude of above 1000 m above sea level.

The total power generated by this balloon can be obtained by means of the relationship

P=Pₛᵤₙ·S·η_{PVA} (16)

We assume that the total collecting area equals to the area of the reflector/collector. Substituting the focal length into Eq. (12) yields S=15.8 m². The average insolation is assumed to be Pₛᵤₙ=500 W/m² and η_{PVA}=0.25 (this value is larger than the spherical case due to the specialized solar cell design). Substituting these values into Eq. (16) yields P=1.97 kW. Hence, the balloon in our example is capable of supplying almost 2 kw of electrical power. The power per unit volume is then

$$\frac{P}{V} = 186 W / {m}^{3} \qquad ( 17 )$$

which is 3.5 better than the power to volume ratio of a spherical balloon.

### Exemplary Materials, Mechanical Design, Aerodynamic and Thermodynamic Considerations

### Exemplary PVA Assembly

In exemplary configurations depicted in FIGS. 2 and 3 and described above, the approximate power output is 2 kW. Assuming a voltage output of 1000 VDC at 2 A is desired, the number of solar cells required to generate 2 kW can be estimated as follows:

The voltage produced by a solar cell is typically 0.6 VDC. If an electrical power system requires a voltage supply of 1000 V, and has 0.6 volt cells connected in series, it will need 1000V/0.6V/cell=1667 cells connected in series.

Since the current supplied by a single solar photovoltaic cell is on the order of 0.01 A, the cells must be connected in parallel to combine the electron flow equivalent to the required current, which, in this example, is 2 A. The total number of cells in parallel would be 2.0 A/0.01 A/cell=200 cells.

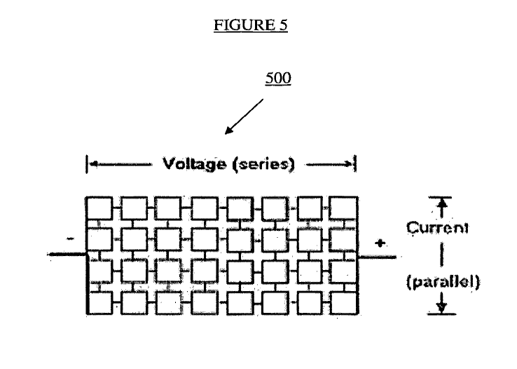

The total array would then be 1667×200 cells. This would develop 1000 V at 2.0 A. This amounts to 2 A×1000V=2 kW of power. A schematic array of this type, generally depicted as 500 is depicted in FIG. 5.

### Exemplary Balloon Materials

Exemplary LAB according to various embodiments of the invention can be constructed from silicon-impregnated material. An exemplary silicon impregnated material is DT891 developed by Linstradt [11]. DT891 is characterized by high tear strength per unit weight. The Silicone-impregnation technique is inherently amenable to manufacturing a fabric with embedded flexible solar arrays, since PVA are typically silicone-based. According to various embodiments of the invention, PVA can be provided as a photovoltaic fabric and/or bonded to fabric via adhesives.

In some exemplary embodiments of the invention, photovoltaic fabric offers better durability. Optionally, bonding via adhesives offers a simpler and less costly manufacturing process. Regardless of how the PVA are provided, gas leaks can be reduced by controlling fabric permeability.

Traditionally, manufacturers have used PVC (polyvinylchloride) to create inflatable materials. However, PVC is characterized by a high weight per unit area and/or a high permeability factor.

In some exemplary embodiments of the invention, urethane is used to fashion LAB. Urethane has a lower weight per unit area, is more durable at a same thickness, and has lower permeability than PVC. The combination of lightweight. Durability and low gas permeability make urethane based inflatable fabrics well suited to use in the context of the invention.

### Exemplary PVA Materials

Different types of PVA are available, though the bulk of the material in use today is silicon-based. In general, PVA materials are categorized as either thick crystalline or thin film (deposited in thin layers on a substrate), polycrystalline or amorphous. In some exemplary embodiments of the invention, thin film PVA are employed. Optionally, thin film PVAs are easily integrated with a surface of the LAB. Several exemplary types of thin-film PVA materials amenable to use in different exemplary embodiments of the invention are briefly described here.

Amorphous Silicon (a-Si): A non-crystalline form of silicon, first used in photovoltaic materials in 1974. In 1996, amorphous silicon constituted more than 15 percent of the worldwide PV production. Small experimental a-Si modules have exceeded 10-percent efficiency, with commercial modules in the 5-7-percent range. Used mostly in consumer products, a-Si technology holds great promise in building-integrated systems, replacing tinted glass with semi-transparent modules.

Cadmium Telluride (CdTe): A thin-film polycrystalline material amenable to electro-deposition, spraying, and high-rate evaporation can contribute to reductions in production cost. Small laboratory devices approach 16-percent efficiency, with commercial-sized modules (7200-cm²) measured at 8.34-percent (NREL-measured total-area) efficiency and production modules at approximately 7 percent.

Copper Indium Diselenide (CuInSe₂, or CIS): A thin-film polycrystalline material, which has reached a research efficiency of 17.7 percent, in 1996, with a prototype power module reaching 10.2 percent. This type of PVA is still in development but offers tremendous potential for high efficiency embodiments of the invention.

### Exemplary Concentrators and Reflectors

Concentrator systems use lenses or reflectors to focus sunlight onto the solar cells or modules. Lenses, with concentration ratios of 10× to 500×, typically Fresnel linear-focus or point-focus lenses, are most often made of an inexpensive plastic material engineered with refracting features that direct the sunlight onto a small or narrow area of cells. The cells are usually silicon. GaAs cells and other materials would have higher conversion efficiencies, and could operate at higher temperatures, but they are often substantially more expensive. Module efficiency can range upwards from 17%, and concentrator cells have been designed with conversion efficiencies in excess of 30%. Reflectors can be used to augment power output, increasing the intensity of light on modules, or to extend the time that sufficient light falls on the modules.

### Exemplary Mechanical Design

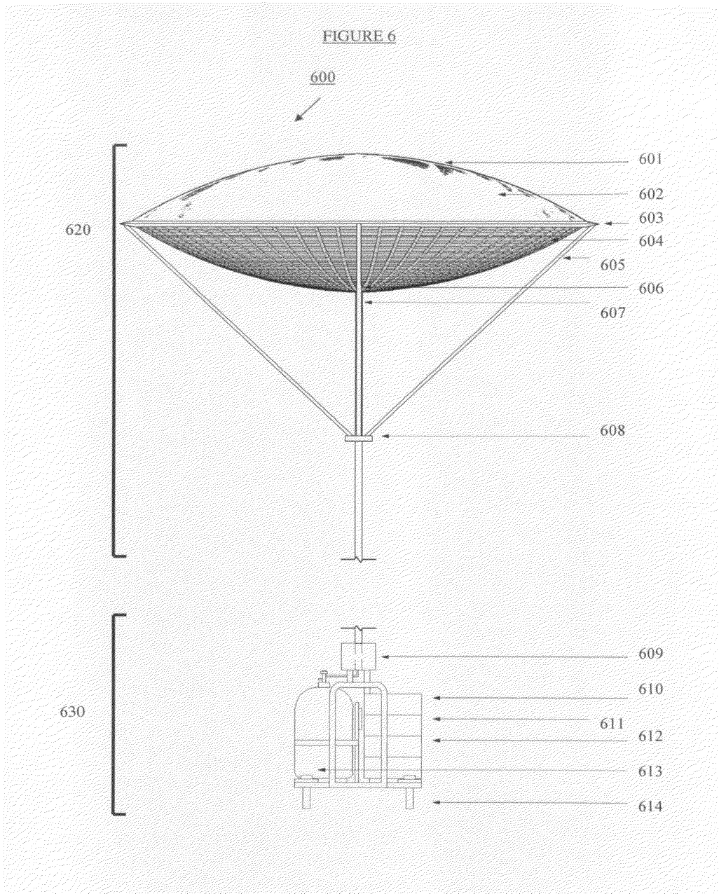

FIG. 6 depicts an exemplary mechanical system 600 in which a generator 620 based on an LAB with integrated PVA is coupled to an interface 630 to a ground based power grid.

In the depicted exemplary embodiment the LAB based generator 620 includes an upper transparent paraboloid 601 and a lower opaque paraboloid 604, an inner surface of which contains an embedded PVA as described hereinabove with reference to FIG. 2. The LAB is filled with helium gas 602. In the depicted embodiment, circumferential seal 230 (FIGS. 2 and 3) is provided as a rigid band 603.

Strapping cables 605 are provided for stabilization of the balloon. Central coaxial isolated cable 607 conducts the DC current groundwards and helium towards the LAB as will be described in greater detail hereinbelow. Cable 607 passes through ring 608 (optionally provided as a ring bearing) which is connected to strapping cables 605. Parts 605, 607 and 608 function as an anchor which connects at least three points on circumferential closure 603 to an anchor point, depicted here as 630. Optionally, ring 608 contributes to mitigation of wind shear.

A pressure valve 606 connects a gas bearing portion of coaxial cable 607 to the LBA. Port 606 can be used for initial gas inflation and/or occasional gas refill/discharge (e.g. for altitude control). In some exemplary embodiments of the invention, helium gas is employed.

Depicted exemplary interface 630 includes a charge controller 609 for regulating and controlling voltage and/or DC/AC inverter 610 for transforming DC power generated by the PVA to an AC power. Optionally, transformation to AC power is performed to voltage AO frequency parameters of a regional electric power grid.

Alternatively or additionally interface 630 includes a battery 611 and/or a rectifier 612. Battery 611 is optionally useful for operation at night or under cloudy conditions. Rectifier 612 is optionally useful for on-grid operation.

Pressurized gas tank 613 is depicted within interface 630, though it is not functionally related to transfer of power to an external power grid. Tank 613 supplies gas via cable 607 to the LAB as needed.

In some exemplary embodiments of the invention, a docking platform 614 is provided. Platform 614 anchors interface 630 at a fixed location. Optionally, platform 514 includes weights and/or a foundation (e.g. concrete pilings partially buried in earth). In embodiments of the invention provided on a ship or other vehicle, platform 614 can be provided as a ring or hook attached to a hull or chassis.

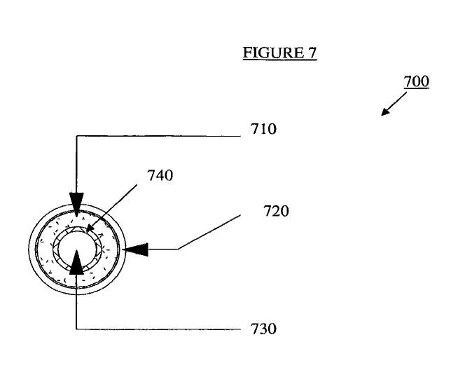

FIG. 7 is a cross sectional view 700 of one exemplary configuration of an optional coaxial cable suitable for use as cable 607 in FIG. 6. In the depicted embodiment concentric insulation layers 720 and 740 divide the cable into inner lumen 730 and outer lumen 710. In some exemplary embodiments of the invention, inner lumen 730 serves to transport Gas (e.g. helium) is transported to the LAB and outer lumen 710 contains conductive material (e.g. copper wires) to transmit electric power to the charge controller and/or to the DC/AC inverter of interface 630. In other embodiments of the invention, the roles of the lumens are reversed. Optionally, pressure valve 606 connected to cable 607 controls helium refill or discharge, optionally through activating tank 613. The inner part of the cable is a conducting wire, used to transport the electric charge to a

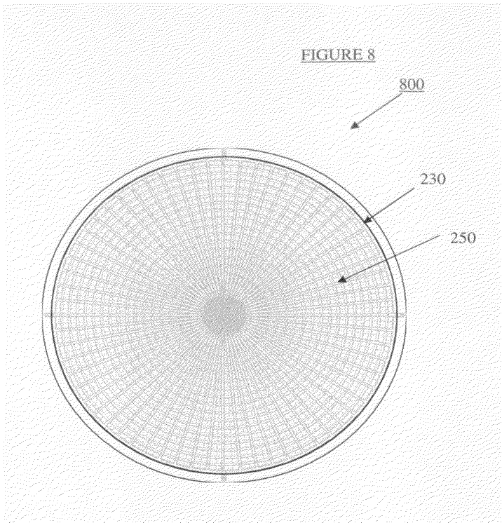

FIG. 8 shows a horizontal cross section 800 of an exemplary LAB with the PVA array arranged in one half of the balloon surrounded by circumferential seal 230 so as to produce the required voltage and current. One option for assembling the PVA is to use a thin-film silicone, as explained above. This results in a considerable weight reduction with only a marginal loss of efficiency.

### Exemplary Aerodynamics in the Pitch Plane

Exemplary LAB according to various embodiments of the invention are subjected to a number of forces during operation. In order to increase durability and robustness of the mechanical design, these forces must be calculated. To that end, an exemplary total force balance in the pitch (vertical) plane computed in a body-fixed reference frame is presented. A similar analysis may be performed in the yaw plane, but is omitted here for the sake of conciseness.

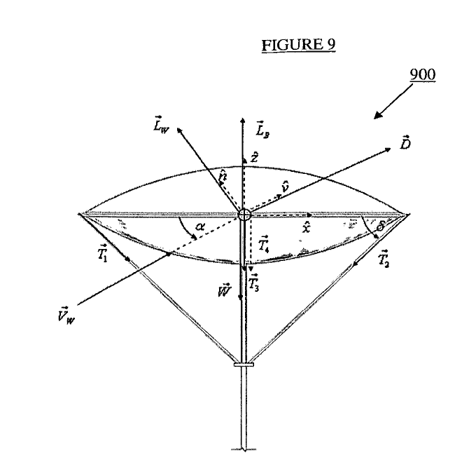

Consider a body-fixed coordinate system, centered at the balloon's center of mass, whose \hat{x}-axis points rightward along the horizontal symmetry plane and whose \hat{z}-axis points upward along the vertical symmetry plane. Let \vec{V}_{w} denote the wind velocity vector, and α be the angle of attack, as shown in FIG. 9. The drag force, \vec{D}, is then given by

$$\vec{D} = \frac{1}{2} ρ {V}_{w}^{2} {S}_{ref} {C}_{D} \hat{v} \qquad ( 18 )$$

where ρ is the atmospheric density, S_{ref} is a reference area, C_{D} is the drag coefficient and \hat{v} is a unit vector along the wind velocity vector, as shown in FIG. 9. The lift force due to wind is given by

$${\vec{L}}_{w} = \frac{1}{2} ρ {V}_{w}^{2} {S}_{ref} {C}_{L} \hat{n} \qquad ( 19 )$$

where C_{L} is the lift coefficient and \hat{n} is a unit vector normal to wind velocity direction.

In addition to the aerodynamical lift, a gas buoyancy lift force, \vec{L}_{B}, acts upon the balloon due to the lighter-than-air medium. This force is given by (cf. Eq. (4))

\vec{L}_{B}=g(ρ−ρ_{He})V_{balloon}\hat{z} (20)

Finally, the balloon weight is

\vec{W}=−mg\hat{z} (21)

The above forces are balanced using the strapping cables 605 tension forces, \vec{T}₁, \vec{T}₂, \vec{T}₃, \vec{T}₄. If equilibrium is assumed, then writing the moment equation about the center of mass will yield* *In reality, the aerodynamic forces act at the aerodynamic center, and not at the center of gravity. We assume herein that the distance from the aerodynamic center to the center of gravity is negligible relative to the balloon size. In the real world, this effect will cause a slightly different tension force in each cable.

\vec{T}₁≈\vec{T}₂≈\vec{T}₃≈\vec{T}₄ (22)

Let δ be the angle between the strapping cable and the balloon horizontal cross section, as shown in FIG. 9. The equilibrium force equation in the \hat{z} direction under the constraint (22) is given by

L_{w} cos α+D sin α+L_{B}=−4T₁ sin δ−W (23)

Substituting the expressions in Eqs. (18)-(21) yields

$$\frac{1}{2} ρ {V}_{w}^{2} {S}_{ref} {C}_{L} cos α + \frac{1}{2} ρ {V}_{w}^{2} {S}_{ref} {C}_{D} sin α + g ( ρ - {ρ}_{He} ) {V}_{balloon} = - 4 {T}_{1} sin δ + mg \qquad ( 24 )$$

Similarly, the equilibrium force equation in the \hat{x} direction is

L_{w} sin α+T₂ cos δ=D cos α+T₁ cos δ (25)

wherefrom we find that

$$\frac{1}{2} ρ {V}_{w}^{2} {S}_{ref} {C}_{L} sin α = \frac{1}{2} ρ {V}_{w}^{2} {S}_{ref} {C}_{D} cos α \qquad ( 26 )$$

For small angles of attack, we may use the approximation cos α≈1, sin α=α. Under this assumption, Eq. (26) simplifies into

$$α \approx \frac{{C}_{D}}{{C}_{L}} \qquad ( 27 )$$

Substituting (27) into (24) yields an estimate of the tension force acting on each cable:

$${T}_{C} \approx - \frac{1}{4 sin δ} [ \frac{1}{2} ρ {V}_{w}^{2} {S}_{ref} {C}_{L} + \frac{1}{2 {C}_{L}} ρ {V}_{w}^{2} {S}_{ref} {C}_{D}^{2} + g ( ρ - {ρ}_{He} ) {V}_{balloon} - mg ] \qquad ( 28 )$$

A negative tension implies that the balloon operates at some designated altitude, while a positive tension implies that the balloon is below the desired altitude. For example, using the numerical values from Section 3, and assuming that C_{L}=0.5, C_{D}=0.1, δ=45° yield a tension force of about 13 kg in each cable for a wind speed of 30 m/s.

FIG. 9 is a schematic 900 depicting exemplary forces acting on exemplary LAB according to various embodiments of the invention using the symbols presented above.

### Exemplary Thermodynamic Considerations

An important engineering constituent of described exemplary systems is the issue of thermodynamic equilibrium. Only a small portion of the incident solar radiation is transformed into electric energy. Most of the incoming energy 240 is transformed into heat, and some is reflected. In order to achieve a thermal equilibrium, the bulk of the heat should be radiated or convected. In the interest of brevity, a thorough thermal analysis is not presented here. However, due to the thermal properties of helium, exemplary systems according to the invention should reach a stable thermal equilibrium. In some cases heating may occur and cause helium density drop. Optionally, the density drop causes a concomitant increase in altitude.

### Exemplary Markets

LAB according to exemplary embodiments of the invention can be individually purchased. Optionally, additional fees will apply for monthly maintenance. Alternatively, LAB according to exemplary embodiments of the invention may be leased for a given period of time by paying a monthly fee that will be about 50% lower than the average cost of electricity. A leased LAB can optionally be operated by a code-protected converter. In some exemplary embodiments of the invention, the code is provided for customers paying the monthly fee only. This model is similar to existing registered user marketing plans.

The potential market encompasses virtually all domestic and commercial users. LAB according to various embodiments of the invention constitute an efficient, infrastructure-free energy source for markets including, but not limited to:
1) Underprivileged third-world communities and disaster regions, in which the existing power infrastructure is deprived or heavily damaged (e.g., East-Asian countries struck by tsunamis, American cities hit by hurricanes).
2) Exemplary LAB according to various embodiments of the invention can be delivered from the air to the above areas (by changing the volume of the balloons one can determine the exact altitude to which the LAB will descend after an airborne delivery).
3) Exemplary LAB according to various embodiments of the invention can be used at sea on marine vessels or on remote islands.
4) Government agencies can purchase bulk quantities of energy-generating balloons to be used in emergency situations.
5) The Exemplary LAB according to various embodiments of the invention are highly portable and can thus be mobilized in compact backpacks by individual users, ground vehicles, ship and aircraft.

Depicted exemplary designs are highly portable, versatile and adaptable and can thus be utilized in diverse applications, ranging from street lighting through cellular phone receiver-transmitter antennae to emergency power generation. Depicted Exemplary systems and/or generators system occupies virtually no area on a roof. This area can be used for alternative urban functions such as roof gardens. In hot regions, the balloon can be used as a shelter and can be also used for advertisement. In wooded areas, the balloon concept considerably facilitates the extraction of solar power.

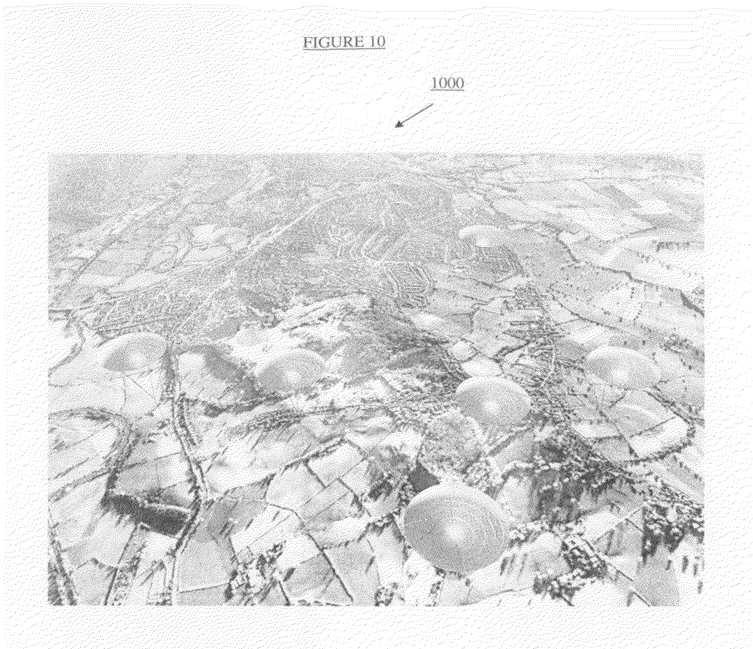

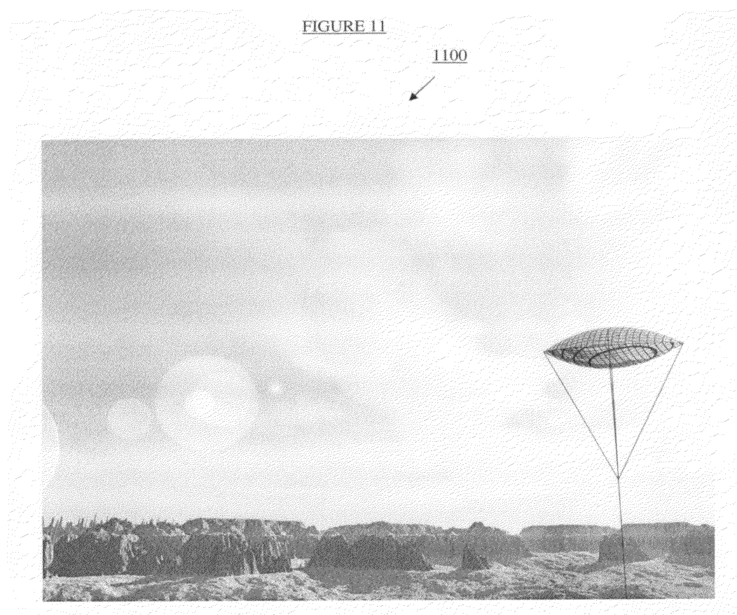

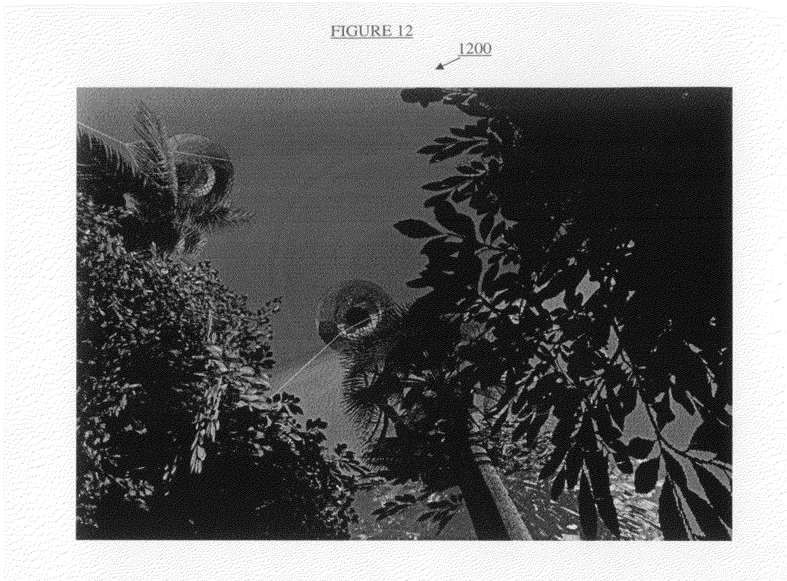

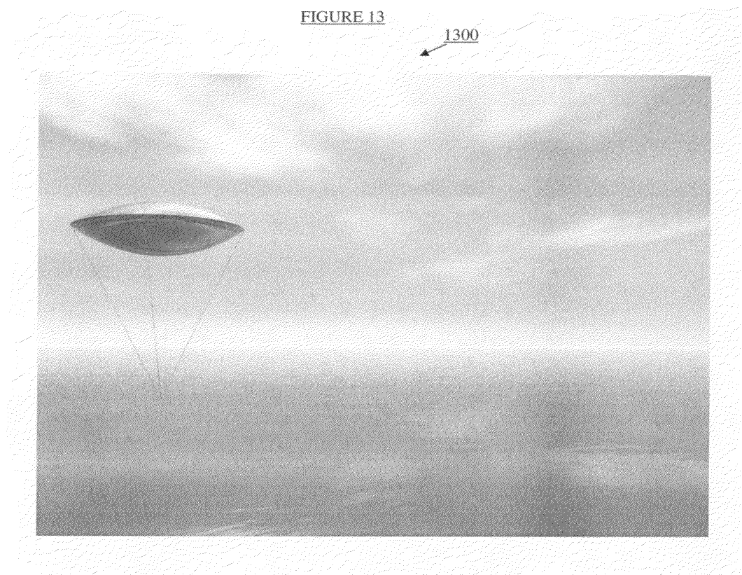

FIGS. 10-13 are renderings of exemplary LAB in exemplary use scenarios, showing the potential applicability to different environments. FIG. 10 depicts an exemplary LAB according to some embodiments of the invention dispersed in a rural area. FIG. 11 depicts an exemplary LAB in an off-grid remote desert location. FIG. 12 depicts exemplary LAB according to embodiments of the invention deployed above a forest canopy. FIG. 13 depicts an exemplary LAB at sea where it can serve as a primary or secondary power source for marine vessels or remote islands

### Exemplary Multi-Balloon Systems

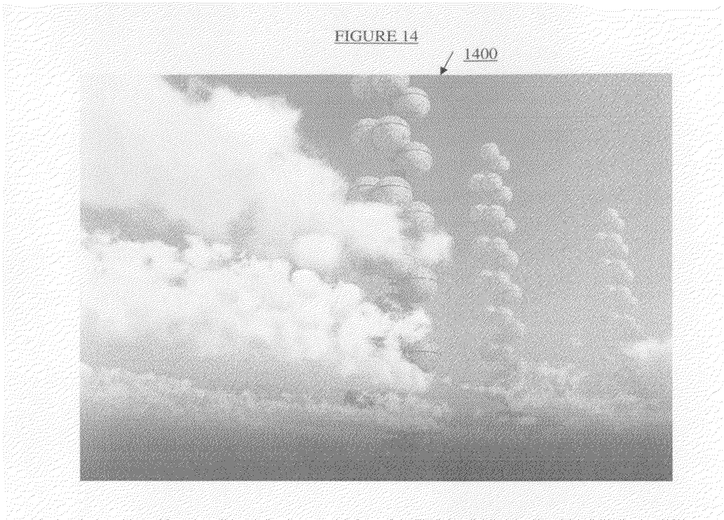

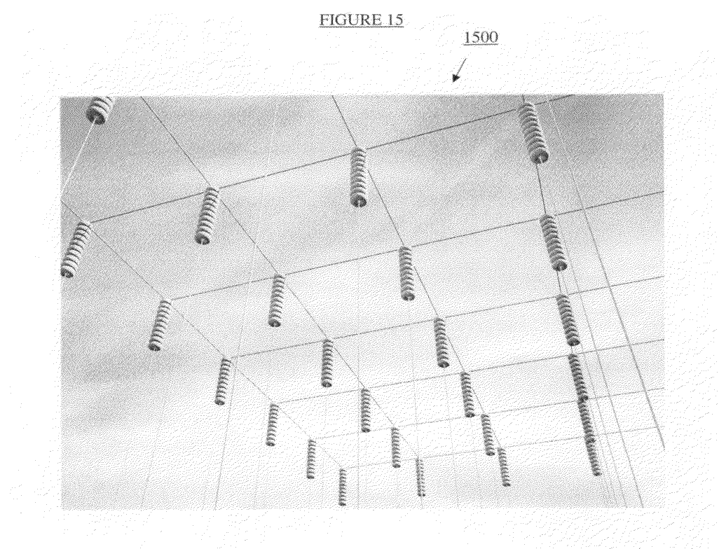

Exemplary LAB according to exemplary embodiments of the invention may be used in a variety of multi-balloon systems including, but not limited to those depicted in FIGS. 14 and 15.

FIG. 14 depicts a plurality of LAB according to exemplary embodiments of the invention assembled to form a three dimensional array of balloons connected to one another (several arrays are depicted). This type of array contributes to an increase in power return and/or enables an increase in a floatation weight of the system and/or the amount of energy produced.

FIG. 15 depicts a plurality of LAB according to exemplary embodiments of the invention assembled to form a three dimensional array of balloons connected to one another in an elongated lighter-than-air grid structures. The depicted lighter than air grid increases the power return while decreasing an environmental signature.

### Exemplary Durability Analysis

It is estimated that the practical life-cycle of exemplary LAB based generators described hereinabove will exceed 15 years.

### Exemplary Applications

LAN based generators are a versatile platform that can be adapted to a myriad of potential consumers. Thus, the commercialization potential is significant. Potential product categories include, but are not limited to:
1. Basic LAB generators (e.g. of the type depicted in FIG. 1) adapted for use as either a primary or a secondary reliable electric energy source in tents, condos, residential areas and high-rise buildings.
2. Advanced LAB generators including a paraboloidic balloon with a bottom collector and an upper transparent part (FIG. 2) or a bottom reflector and an upper collector (FIG. 3) provide a smooth aerodynamic design. This type of design is well suited for marine vessels. Future applications may include arrays of LAB of this type which are inter-connected and/or inter communicating.
3. LAB based power stations based upon a combination of a large number of LAB based generators in various altitudes can create a lighter-than-air power station via the concept of Lighter-than-Air Solar Grid Deployment as depicted in FIGS. 14 and 15.

### Exemplary Advantages

The new ecological paradigm described herein has several clear advantages. In some exemplary embodiments of the invention, LAN based generators transform light into electricity without occupying precious land area. Optionally, this contributes to accessibility, portability and reduced infrastructure requirements. Optionally, these solutions are suitable for use in remote areas and/or at sea.

Exemplary LAB based generators according to various embodiments of the invention constitute an affordable, easily installable and durable energy platform that does not affect the environment due to its modular plug-and-play design. Each balloon is manufactured from thin-films of amorphous silicon using a simple, inexpensive, environmentally-friendly process, supporting mass production and accessibility to a wide spectrum of consumers. Various embodiments of the invention utilize modern PV technology while maintaining simplicity as well as elegance—the PV system, similarly to the sun, will be almost invisible to “land dwellers”—but will be nevertheless efficient and iconic.

Optionally, embodiments of the invention are socially, as well as environmentally friendly. In some exemplary embodiments of the invention, existing gaps in solar-power accessibility are reduced. This “acupuncture” technology will be suitable for diverse cultural needs and ubiquitous applications, maintaining full accessibility to green places on the ground and as well as on the rooftops; The diversity of potential markets is achieved by designing a product that fits both on-grid and off-grid operations. This multi-pronged deployment strategy interacts with local renewable energy distributors. In some exemplary embodiments of the invention, such interaction increases market penetration and/or is amenable to franchise distribution. In some exemplary embodiments of the invention, local partners assume responsibility for operations in their local region, including inventory handling, payment collection, product distribution and maintenance and repair. Use of local partners can introduce new employment opportunities to the local community and will increase involvement and interaction of the community.

In some exemplary embodiments of the invention, PV technologies are provided in a spatial arrangement that functions as an aesthetic object and sends an educational message in addition to promoting a higher community independence of external energy. The various described embodiments embrace technology as well as addressing the need to make this important energy awareness reachable to all sectors of society.

Environmental benefits are clear because of the minimal ecological footprint of this alternative energy resource, which constitutes a clean, non-polluting energy infrastructure.

Hanging the PV in the air will decrease pollution in cities as well as reduce noise and visual footprint (in warm countries, the system can be lowered and used to produce shading as well). The system can be maintained locally and will serve as an inexpensive, affordable, cost effective, accessible, durable and competitive energy source.

By putting 500-1000 solar balloons above rural landscape for example, it is possible to generate more than 1 MW of power in an innovative way. The innovation is based on fusion of existing technologies (Balloons and PVA) in a new, optimized shape of embedded lighter-than-air craft maximizing power return for a given volume. The spherical shape has a maximum exposure to the sun with no need to control and direct the balloons to a specific angle. This renders the low-tech balloon free of any kind of maintenance or control; and therefore they are less expensive. The grid system is made of light cables several meters apart. In the future, more balloons can be added to each cable, augmenting the energy output without having to change anything on the ground. This literally generates Endless Energy Columns with numerous possibilities for balloon array arrangements.

The green spaces in between buildings will stay as a social meeting space for many more years. Commercial buildings, public spaces and social housing will be able to share the same technology and amount of energy. The distributed grid layout will prevent failure of the entire system, new balloons can be added and failed balloons can be easily replaced or refilled with helium.

The constant growth of energy demands increases the need to decrease pollution. Energy crisis will require alternative energy solutions. Various described embodiments of the invention provide an inexpensive solar power system, which will improve human access to clean energy through the use of simple and clean technology of lighter-than-air platforms. Energy should be Social, Ecological, Reliable, Individual, Efficient and Simple to use.

It is expected that during the life of this patent many types of PVA will be developed and the scope of the invention is intended to include all such new technologies a priori.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

Specifically, a variety of numerical indicators have been utilized. It should be understood that these numerical indicators could vary even further based upon a variety of engineering principles, materials, intended use and designs incorporated into the invention. Additionally, components and/or actions ascribed to exemplary embodiments of the invention and depicted as a single unit may be divided into subunits. Conversely, components and/or actions ascribed to exemplary embodiments of the invention and depicted as sub-units/individual actions may be combined into a single unit/action with the described/depicted function.

Alternatively, or additionally, features used to describe a method can be used to characterize an apparatus and features used to describe an apparatus can be used to characterize a method.

It should be further understood that the individual features described hereinabove can be combined in all possible combinations and sub-combinations to produce additional embodiments of the invention. The examples given above are exemplary in nature and are not intended to limit the scope of the invention which is defined solely by the following claims.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention.

The terms “include”, and “have” and their conjugates as used herein mean “including but not necessarily limited to”.

### REFERENCES

[1] Gandorfer, A. M., Solanki, S. K., Barthol, P., Lites, B. W., Martinez-Soltau, D., and Tile, A. M., “SUNRISE: High-Resolution UV/VIS Observatories of the Sun from the Stratosphere”, Proceedings of the SPIE, Vol. 6267, June 2006.
[2] Wenzel, J., “Solar Power Station”, U.S. Pat. No. 4,361,295, 1980.
[3] Hall, F. F., “Solar Energy Collector Including a Weightless Balloon with Sun Tracking Means”, U.S. Pat. No. 4,126,123, 1978.
[4] Stark, V., “Apparatus for Collecting Solar Energy at High Altitudes and on Floating Structures”, U.S. Pat. No. 4,364,532, 1982.
[5] Solar Spectra: Standard Air Mass Zero. NREL Renewable Resource Data Center Retrieved October 2006.
[6] Earth Radiation Budget. NASA Langley Research Center, Retrievd October 2006.
[7] NREL: Dynamic Maps, GIS Data, and Analysis Tools—Solar Maps.
[8] National Renewable Energy Laboratory, US., Retrievd September 2006.
[9] Gray, A. “The Paraboloid.” §13.5 in Modern Differential Geometry of Curves and Surfaces with Mathematica, 2nd ed. Boca Raton, Fla.: CRC Press, pp. 307-308, 1997.
[10] Harris, J. W. and Stocker, H. “Paraboloid of Revolution.” §4.10.2 in Handbook of Mathematics and Computational Science. New York: Springer-Verlag, p. 112, 1998.
[11] The Linstradt webpage: http://wwwDOTlinstradtDOTcom.
[12] U.S. Standard Atmosphere, 1976, U.S. Government Printing Office, Washington, D.C., 1976.

1. An electric power generator, the generator comprising:
at least one lighter than air balloon (LAB) with at least one photovoltaic array (PVA) embedded in a surface thereof; and
a cable connecting the LAB to the ground and adapted to convey a buoyant gas to an inner volume of the LAB and also to convey an electric current generated by said PVA to a ground installation.

2. A generator according to claim 1, wherein said PVA are embedded in an outer surface of said LAB.

3. A generator according to claim 1, wherein a portion of said LAB is transparent with respect to desired wavelengths of light.

4. A generator according to claim 3, wherein said PVA are embedded in an inner surface of said LAB.

5. A generator according to claim 3, wherein at least a portion of an inner surface of said LAB is reflective with respect to said desired wavelengths of light.

6. A generator according to claim 1, wherein said LAB comprises:
a lower paraboloid portion; and
an upper paraboloid portion inverted with respect to said lower paraboloid portion.

7. An electric power generator, the generator comprising:
at least one lighter than air balloon (LAB) comprising an upper portion constructed of material transparent with respect to desired wavelengths of incident light and a lower portion adapted to receive said desired wavelengths of incident light on an inner surface thereof; and
at least one photovoltaic arrays (PVA) on an inner surface of said LAB.

8. A generator according to claim 7, wherein said at least one PVA resides on said inner surface of said lower portion.

9. A generator according to claim 7, wherein said at least one PVA resides on an inner surface of said upper portion and wherein said lower portion receives said desired wavelengths of incident light on a reflective inner surface which directs said light to said PVA.

10. A generator according to claim 7, wherein at least one of said upper portion and said lower portion is configured as a paraboloid.

11. A generator according to claim 10, wherein said upper portion and said lower portion are each configured as paraboloids inverted with respect to one another.

12. An anchored lighter than air balloon (LAB), the balloon comprising:
an upper portion and a lower portion, each of said portions configured as paraboloids inverted with respect to one another;
a circumferential closure joining said upper and lower portions; and
an anchor connecting at least three points on said circumferential closure to an anchor point.

13. An LAB according to claim 12, wherein said anchor is adapted to convey a buoyant gas to said balloon.

14. An LAB according to claim 12, comprising:
at least one PVA embedded in a surface of the balloon.

15. A generator according to claim 1, comprising an interface to a ground based power grid.

16. A power supply system, the system comprising:
a plurality of generators according to claim 1 deployed in a three dimensional array and connected to one another; and
an interface to a ground based power grid.

17. A generator according to claim 7, comprising an interface to a ground based power grid.

18. A power supply system, the system comprising:
a plurality of generators according to claim 7 deployed in a three dimensional array and connected to one another; and
an interface to a ground based power grid.

19. An LAB according to claim 14 comprising an interface between said PVA and a ground based power grid.

20. A power supply system, the system comprising:
a plurality of LAB according to claim 14 deployed in a three dimensional array and connected to one another, and
an interface between said PVA of said plurality of LAB and a ground based power grid.
